(19) United States
(12) Patent Application Publication
(10) Pub. No.: US 2023/0314357 A1
(43) Pub. Date: Oct. 5, 2023

(54) STRUCTURE FOR DETECTING CRACK AND SEMICONDUCTOR DEVICE

(71) Applicant: Changxin Memory Technologies, Inc., Hefei City (CN)

(72) Inventors: Li Tang, Hefei City (CN); Cheng Chen, Hefei City (CN); Wei Jiang, Hefei City (CN)

(21) Appl. No.: 17/811,953

(22) Filed: Jul. 12, 2022

Related U.S. Application Data
(63) Continuation of application No. PCT/CN2022/094676, filed on May 24, 2022.

(30) Foreign Application Priority Data
Mar. 31, 2022 (CN) 202210332067.X

(51) Int. Cl. G01N 27/20; H01L 21/66

(52) U.S. Cl. CPC G01N 27/20; H01L 22/34

(57) ABSTRACT

The present disclosure provides a structure for detecting a crack and a semiconductor device. The structure for detecting a crack includes at least three metal layers, and an interconnection via layer is provided between adjacent metal layers. The structure for detecting a crack further includes multiple detection units. The detection unit includes an intermediate metal segment and at least two metal segment groups. Each of the metal segment groups includes a first metal segment and a second metal segment located in a same metal layer and spaced apart. The intermediate metal segment and each of the metal segment groups are located in different metal layers, and different metal segment groups are located in different metal layers.

### CROSS-REFERENCE TO RELATED APPLICATIONS

This is a continuation of International Application No. PCT/CN2022/094676, filed on May 24, 2022, which is based on and claims the priority to Chinese Patent Application No. 202210332067.X, titled “STRUCTURE FOR DETECTING CRACK AND SEMICONDUCTOR DEVICE” and filed on Mar. 31, 2022. The entire contents of International Application No. PCT/CN2022/094676 and Chinese Patent Application No. 202210332067.X are incorporated herein by reference.

### TECHNICAL FIELD

The present disclosure relates to the technical field of semiconductors, and in particular, to a structure for detecting a crack and a semiconductor device.

### BACKGROUND

In a process of manufacturing a semiconductor chip, a slicing operation needs to be performed on a wafer on which multiple semiconductor chips are formed. During the slicing operation, tiny cracks may be caused on edges of the semiconductor chips. If the cracks extend into the semiconductor chips, integrated circuits (ICs) inside the semiconductor chips may be damaged. Therefore, a structure for detecting a crack needs to be provided on the semiconductor chip to perform crack detection.

However, use of the structure for detecting a crack can hardly reflect an overall crack status of edges of the semiconductor chip, resulting in an inaccurate detection result.

### SUMMARY

An overview of the subject matter detailed in the present disclosure is provided below, which is not intended to limit the protection scope of the claims.

The present disclosure provides a structure for detecting a crack and a semiconductor device.

According to a first aspect of embodiments of the present disclosure, a structure for detecting a crack is provided, wherein the structure for detecting a crack includes at least three metal layers, and an interconnection via layer is provided between adjacent metal layers;
the structure for detecting a crack further includes multiple detection units, the detection unit includes an intermediate metal segment and at least two metal segment groups, each of the metal segment groups includes a first metal segment and a second metal segment located in a same metal layer and spaced apart, the intermediate metal segment and each of the metal segment groups are located in different metal layers, and different metal segment groups are located in different metal layers; and
the first metal segment and the second metal segment in a metal segment group adjacent to the intermediate metal segment are respectively connected to the intermediate metal segment through two first interconnection via structures located in a same interconnection via layer; and two first metal segments in adjacent metal segment groups and two second metal segments in the adjacent metal segment groups are respectively connected through two second interconnection via structures located in a same interconnection via layer, wherein
along a direction from the intermediate metal segment to the metal segment group, a distance between an outer endpoint of the first metal segment and an outer endpoint of the second metal segment in a metal segment group away from the intermediate metal segment is greater than a distance between an outer endpoint of the first metal segment and an outer endpoint of the second metal segment in a metal segment group close to the intermediate metal segment.

A second aspect of the present disclosure provides a semiconductor device, comprising a chip region and a peripheral region surrounding the chip region, wherein the structure for detecting a crack described above is provided in the peripheral region.

Other aspects of the present disclosure are understandable upon reading and understanding of the accompanying drawings and detailed description.

### BRIEF DESCRIPTION OF THE DRAWINGS

The accompanying drawings incorporated into the specification and constituting part of the specification illustrate the embodiments of the present disclosure, and are used together with the description to explain the principles of the embodiments of the present disclosure. In these accompanying drawings, similar reference numerals are used to represent similar elements. The accompanying drawings in the following description are some rather than all of the embodiments of the present disclosure. Those skilled in the art may derive other accompanying drawings based on these accompanying drawings without creative efforts.

FIG. 1 is a schematic structural diagram of a structure for detecting a crack according to an exemplary embodiment;

FIG. 2 is a schematic structural diagram of a detection unit in a structure for detecting a crack according to an exemplary embodiment;

FIG. 3 is a schematic structural diagram of a detection unit in a structure for detecting a crack according to an exemplary embodiment;

FIG. 4 is a top view of the detection unit shown in FIG. 3;

FIG. 5 is a schematic structural diagram of multiple detection units in a structure for detecting a crack according to an exemplary embodiment;

FIG. 6 is a schematic structural diagram of multiple detection units in a structure for detecting a crack according to an exemplary embodiment;

FIG. 7 is a schematic structural diagram of a detector ring in a structure for detecting a crack according to an exemplary embodiment;

FIG. 8 is a schematic structural diagram of multiple detection units forming multiple detector rings in a structure for detecting a crack according to an exemplary embodiment;

FIG. 9 is a schematic structural diagram of multiple detection units forming multiple detector rings in a structure for detecting a crack according to an exemplary embodiment;

FIG. 10 is a schematic structural diagram of multiple detection units forming multiple detector rings in a structure for detecting a crack according to an exemplary embodiment; and

FIG. 11 is a schematic structural diagram of a semiconductor device according to an exemplary embodiment.

### REFERENCE NUMERALS

100. metal layer; 101. first metal layer; 102. second metal layer; 103. third metal layer; 200. interconnection via layer; 210. first interconnection via structure; 220. second interconnection via structure; 201. first interconnection via layer; 202. second interconnection via layer; 300. detection unit; 310. intermediate metal segment; 320. metal segment group; 321. first metal segment; 322. second metal segment; 301. first detection unit; 302. second detection unit; 400. isolation layer; 500. detector ring; 510. first endpoint; 520. second endpoint; 530. opening; 501. first detector ring; 502. second detector ring; 600. substrate;
10. chip region; 20. peripheral region; 30. structure for detecting a crack; 40. protection ring; 50. slicing slot.

### DETAILED DESCRIPTION

The technical solutions in the embodiments of the present disclosure are described below clearly and completely with reference to the accompanying drawings in the embodiments of the present disclosure. Apparently, the described embodiments are merely some rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

During slicing of a wafer, cracks are easily caused on edges of a semiconductor chip due to multiple factors such as a width of a slicing slot, a speed of a slicing blade, a generate air flow, a pressure, and a temperature, resulting in serious semiconductor chip failure and reliability and quality problems. Therefore, a structure for detecting a crack needs to be provided in the semiconductor chip to cooperate with a detection circuit to perform crack detection.

For example, the semiconductor chip has a chip region and a peripheral region surrounding the chip region. Metal lines for crack detection are provided in the peripheral region. The metal lines are located in a top metal layer of the semiconductor chip and form a crack detector ring surrounding the chip region. After a slicing operation is performed on the semiconductor chip, an edge crack status of the semiconductor chip can be determined by detecting the detector ring.

The detector ring is located in the top metal layer of the semiconductor chip. Consequently, the detection is limited, and it is difficult to reflect an overall edge crack status of the semiconductor chip. Therefore, metal segments for crack detection can be arranged in multiple metal layers. For example, multiple metal segment groups are provided in the peripheral region of the semiconductor chip, each metal segment group includes multiple metal segments correspondingly arranged in sequence from top to bottom, and multiple metal segments cross all metal layers of the semiconductor chip, to better reflect the overall edge crack status of the semiconductor chip. However, in order to ensure that the metal segment groups can implement crack detection on an entire periphery of the semiconductor chip, a large quantity of metal segment groups need to be arranged in the peripheral region. As a result, costs are increased, and a spacing between adjacent metal segment groups affects accuracy of the detection.

Based on this, an exemplary embodiment of the present disclosure provides a structure for detecting a crack, provided with multiple detection units, the detection units each include an intermediate metal segment and at least two metal segment groups, the intermediate metal segment and each of the metal segment groups are located in different metal layers, and along a direction from the intermediate metal segment to the metal segment group, a distance between an outer endpoint of a first metal segment and an outer endpoint of a second metal segment in the metal segment group gradually increases to form a step-shaped structure crossing multiple metal layers, such that the detection unit can reflect a crack status of the multiple metal layers, and the step-shaped structure can enable the detection unit to extend as long as possible on an edge of a chip at which the detection unit is located while crossing as many metal layers as possible, which can improve detection accuracy of the detection unit and reduce costs.

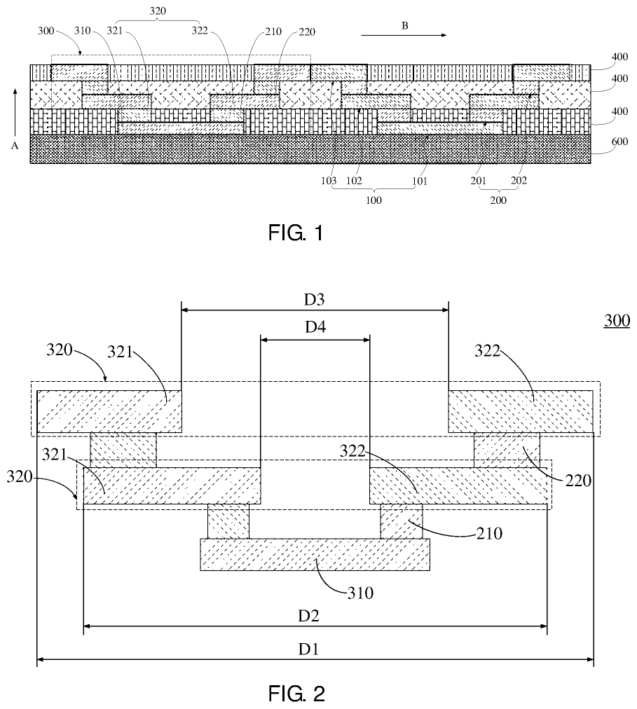

An exemplary embodiment of the present disclosure provides a structure for detecting a crack. As shown in FIG. 1, the structure for detecting a crack includes at least three metal layers 100. For example, the metal layers 100 are provided on the substrate 600. An interconnection via layer 200 is provided between adjacent metal layers 100. A material of each of the metal layers 100 may be, for example, one or more of tungsten (W), aluminum (Al), copper (Cu), silver (Ag), gold (Au), or platinum (Pt). The materials of the metal layers 100 may be the same or different. The metal layer 100 may be a metal interconnection layer in a back end of line (BEOL) process. The interconnection via layer 200 is configured to implement electrical connection between adjacent metal layers 100. For example, the interconnection via layer 200 includes an interconnection via structure (Via). The adjacent metal layers 100 are interconnected through the interconnection via structure.

The structure for detecting a crack further includes multiple detection units 300. As shown in FIG. 2, the detection units 300 each include an intermediate metal segment 310 and at least two metal segment groups 320. Each metal segment group 320 includes a first metal segment 321 and a second metal segment 322 located in a same metal layer 100 and spaced apart. The intermediate metal segment 310 and each of the metal segment groups 320 are located in different metal layers 100, and different metal segment groups 320 are located in different metal layers 100. For example, as shown in FIG. 1, the metal layers 100 in the structure for detecting a crack include a first metal layer 101, a second metal layer 102, and a third metal layer 103 in sequence from bottom to top. The detection units 300 each include the intermediate metal segment 310 and two metal segment groups 320 provided in sequence from bottom to top. The intermediate metal segment 310 is located in the first metal layer 101. A metal segment group 320 close to the intermediate metal segment 310 is located in the second metal layer 102. A metal segment group 320 away from the intermediate metal segment 310 is located in the third metal layer 103.

Referring to FIG. 2, a first metal segment 321 and a second metal segment 322 in a metal segment group 320 adjacent to the intermediate metal segment 310 are respectively connected to the intermediate metal segment 310 through two first interconnection via structures 210 located in a same interconnection via layer 200. Two first metal segments 321 in adjacent metal segment groups 320 and two second metal segments 322 in adjacent metal segment groups 320 are respectively connected through two second interconnection via structures 220 located in a same interconnection via layer 200. Still using FIG. 1 as an example, the interconnection via layer 200 between the first metal layer 101 and the second metal layer 102 is a first interconnection via layer 201, the interconnection via layer 200 between the second metal layer 102 and the third metal layer 103 is a second interconnection via layer 202, and an isolation layer 400 is provided between the first metal layer 101 and the second metal layer 102 and between the second metal layer 102 and the third metal layer 103 to implement isolation between the metal layers 100 or between metal segments in the metal layers 100. The first interconnection via structure 210 is located in the first interconnection via layer 201. The second interconnection via structure 220 is located in the second interconnection via layer 202.

Along a direction (a direction A in FIG. 1) from the intermediate metal segment 310 to the metal segment group 320, a distance between an outer endpoint of a first metal segment 321 and an outer endpoint of a second metal segment 322 in a metal segment group 320 away from the intermediate metal segment 310 is greater than a distance between an outer endpoint of a first metal segment 321 and an outer endpoint of a second metal segment 322 in a metal segment group 320 close to the intermediate metal segment 310, that is, along the direction A, a distance between an outer endpoint of a first metal segment 321 and an outer endpoint of a second metal segment 322 in a metal segment group 320 gradually increases, such that the detection units 300 form a step-shaped structure. For example, as shown in FIG. 2, the distance is between the outer endpoint of the first metal segment 321 and the outer endpoint of the second metal segment 322 in the metal segment group 320 away from the intermediate metal segment 310 is D1, the distance between the outer endpoint of the first metal segment 321 and the outer endpoint of the second metal segment 322 in the metal segment group 320 close to the intermediate metal segment 310 is D2, and the distance D1 is greater than D2.

In this embodiment, through the structure design of the detection unit 300, the detection unit 300 can reflect a crack status of multiple metal layers 100, and the step-shaped structure can enable the detection unit 300 to extend as long as possible on an edge of a chip at which the detection unit 300 is located while crossing as many metal layers 100 as possible, which can improve detection accuracy of the detection unit 300 and reduce costs. In addition, the step-shaped detection unit 300 can be formed as a continuous structure with a large span in both a longitudinal direction (for example, the direction A) and a lateral direction (for example, a direction B in FIG. 1) to further ensure the detection accuracy of the detection unit 300.

It can be understood that, in this embodiment, the metal layers 100 are at least three layers, or may be set to four, five, or more layers according to specific requirements. A quantity of detection units 300 is not limited. For example, multiple detection units 300 are arranged on each side of the semiconductor chip to ensure the detection accuracy.

In some embodiments, distances between the first metal segments 321 and the second metal segments 322 in the metal segment groups 320 are equal to ensure surface flatness of the structure for detecting a crack.

In some other embodiments, as shown in FIG. 2, along the direction from the intermediate metal segment 310 to the metal segment group 320, for example, the direction A, a spacing between the first metal segment 321 and the second metal segment 322 in the metal segment group 320 away from the intermediate metal segment 310 is greater than a spacing between the first metal segment 321 and the second metal segment 322 in the metal segment group 320 close to the intermediate metal segment 310, that is, along the direction A, a spacing between a first metal segment 321 and a second metal segment 322 in a metal segment group 320 gradually increases. For example, as shown in FIG. 2, the distance between the first metal segment 321 and the second metal segment 322 in the metal segment group 320 away from the intermediate metal segment 310 is D3, the distance between the first metal segment 321 and the second metal segment 322 in the metal segment group 320 close to the intermediate metal segment 310 is D4, and the distance D3 is greater than D4.

In this embodiment, because along the direction A, the distance between the outer endpoint of the first metal segment 321 and the outer endpoint of the second metal segment 322 in the metal segment group 320 gradually increases, the distance between the first metal segment 321 and the second metal segment 322 in the metal segment group 320 is also set to gradually increase to effectively reduce a length of the first metal segment 321 and a length of the second metal segment 322 in each metal segment group 320 to further reduce costs while ensuring that the intermediate metal segment 310 is connected to the first metal segment 321 and the second metal segment 322, adjacent first metal segments 321 are connected, and adjacent second metal segments 322 are connected.

In some embodiments, there is a spacing between an edge profile of projection of the first interconnection via structure 210 on the intermediate metal segment 310 and an edge profile of the intermediate metal segment 310, and there is a spacing between an edge profile of projection of the first interconnection via structure 210 on the first metal segment 321 or the second metal segment 322 connected to the first interconnection via structure 210 and an edge profile of the first metal segment 321 or the second metal segment 322. For example, as shown in FIG. 2, the first interconnection via structure 210 connecting the first metal segment 321 and the intermediate metal segment 310 is located between a left edge of the intermediate metal segment 310 and a right edge of the first metal segment 321. The first interconnection via structure 210 connecting the second metal segment 322 and the intermediate metal segment 310 is located between a right edge of the intermediate metal segment 310 and a left edge of the second metal segment 322. Through the structure design described above, the first interconnection via structure 210 forms a reliable connection between the first metal segment 321, the second metal segment 322, and the intermediate metal segment 310.

Similarly, there is a spacing between an edge profile of projection of the second interconnection via structure 220 connecting two first metal segments 321 on the first metal segment 321 located on a lower side and an edge profile of the first metal segment 321 located on the lower side, and there is a spacing between an edge profile of projection of the second interconnection via structure 220 on the first metal segment 321 located on an upper side and an edge profile of the first metal segment 321 located on the upper side. For example, as shown in FIG. 2, there is a spacing between a left edge of the second interconnection via structure 220 connecting the two first metal segments 321 and a left edge of the first metal segment 321 located on the lower side, and there is a spacing between a right edge of the second interconnection via structure 220 and a right edge of the first metal segment 321 located on the upper side. The design of the second interconnection via structure 220 connecting two second metal segments 322 is similar to that of the second interconnection via structure 220 connecting two first metal segments 321, and details are not described again. Through the structure design described above, the second interconnection via structure 220 forms a reliable connection between the first metal segments 321 and between the second metal segments 322.

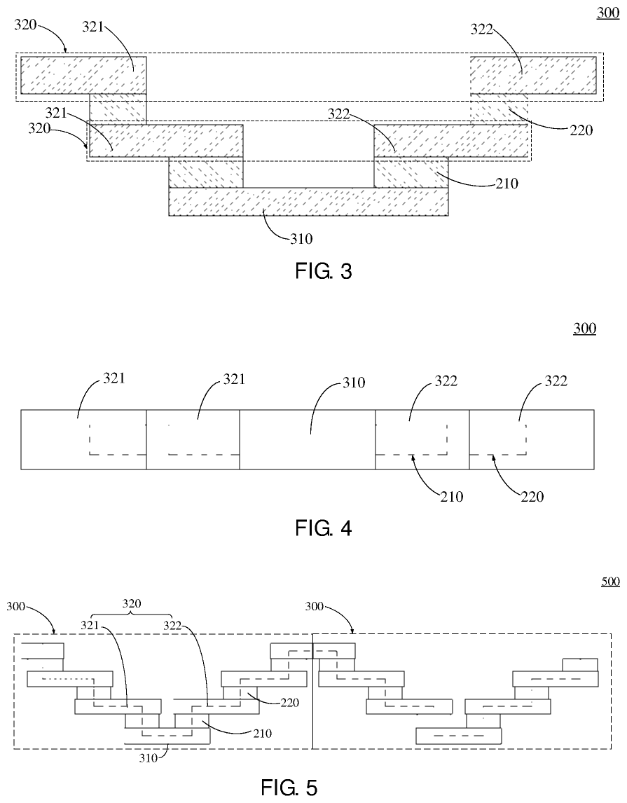

In some other embodiments, the first interconnection via structure 210 has one side edge flush with the intermediate metal segment 310 and the other side edge flush with an edge of the first metal segment 321 or the second metal segment 322 connected thereto. For example, as shown in FIG. 3 and FIG. 4, the first interconnection via structure 210 connecting the first metal segment 321 and the intermediate metal segment 310 has a left edge flush with the left edge of the intermediate metal segment 310 and a right edge flush with the right edge of the first metal segment 321. The first interconnection via structure 210 connecting the second metal segment 322 and the intermediate metal segment 310 has a right edge flush with a right edge of the intermediate metal segment 310 and a left edge flush with the left edge of the second metal segment 322. Through the design described above, a size of the first interconnection via structure 210 can be reduced while the reliable connection between the intermediate metal segment 310 and the first metal segment 321 and the reliable connection between the intermediate metal segment 310 and the second metal segment 322 are ensured, thereby further reducing costs.

Similarly, the second interconnection via structure 220 connecting the two first metal segments 321 has one side edge flush with the first metal segment 321 located on the lower side and the other side edge flush with the first metal segment 321 located on the upper side. For example, as shown in FIG. 3, the second interconnection via structure 220 connecting two first metal segments 321 has a left edge flush with a left edge of the first metal segment 321 located on the lower side and a right edge flush with a right edge of the first metal segment 321 located on the upper side. The design of the second interconnection via structure 220 connecting two second metal segments 322 is similar to that of the second interconnection via structure 220 connecting two first metal segments 321, and details are not described again. Through the design described above, a size of the second interconnection via structure 220 can be reduced while the reliable connection between the first metal segments 321 and the reliable connection between the second metal segments 322 are ensured, thereby further reducing costs.

In an embodiment, an area of a projection of the intermediate metal segment 310 on a first plane, an area of a projection of the first metal segment 321 on the first plane, and an area of a projection of the second metal segment 322 on the first plane are all larger than an area of a projection of the first interconnection via structure 210 on the first plane and are all larger than an area of a projection of the second interconnection via structure 220 on the first plane, and the first plane is parallel to the metal layer 100. Through such a design, costs can be reduced while the reliable connection between the intermediate metal segment 310 and the first metal segment 321 and the reliable connection between the intermediate metal segment 310 and the second metal segment 322 are ensured. For example, as shown in FIG. 4, the intermediate metal segment 310, the first metal segment 321, the second metal segment 322, the first interconnection via structure 210, and the second interconnection via structure 220 are all long strips. Length of the intermediate metal segment 310, length of the first metal segment 321, and length of the second metal segment 322 are all greater than a length of the first interconnection via structure 210 and are all greater than a length of the second interconnection via structure 220. Width of the intermediate metal segment 310, width of the first metal segment 321, and width of the second metal segment 322 are all greater than a width of the first interconnection via structure 210 and are all greater than a width of the second interconnection via structure 220.

Shapes and sizes of a first metal segment 321 and a second metal segment 322 in a same metal segment group 320 may be the same or different. In an exemplary embodiment, as shown in FIG. 2, a first metal segment 321 and a second metal segment 322 in a same metal segment group 320 are symmetrically provided with respect to a perpendicular bisector of the intermediate metal segment 310. For example, when the intermediate metal segment 310 is of a long strip structure, the perpendicular bisector thereof is a line passing through a center of the intermediate metal segment 310 and perpendicular to the intermediate metal segment 310. The symmetrical arrangement of the first metal segment 321 and the second metal segment 322 with respect to the perpendicular bisector of the intermediate metal segment 310 can facilitate layout design, improve layout design efficiency, and improve structural uniformity in a manufacturing process. When the multiple detection units 300 include detection units 300 arranged one above another, such a symmetrical structure is more conducive to the layout of the detection units 300, avoiding structural interference.

As described above, one detection unit 300 includes at least two metal segment groups 320 to form a step-shaped detection unit 300. Certainly, it can be understood that one detection unit 300 may alternatively include more than two metal segment groups 320, for example, three metal segment groups 320, as shown in FIG. 5. In an exemplary embodiment, a number of the metal segment groups 320 in the detection unit 300 is 2 to 5, and the quantity of metal segment groups 320 may be selected based on a BEOL process condition of the semiconductor chip and actual requirements, to ensure reliability of connection between metal segments and crack detection accuracy.

In a detection unit 300, a thickness of the intermediate metal segment 310, a thickness of the first metal segment 321, and a thickness of the second metal segment 322 may be the same to simplify the process. In some other embodiments, from top to bottom, thicknesses of the metal segments gradually decrease to ensure detection sensitivity.

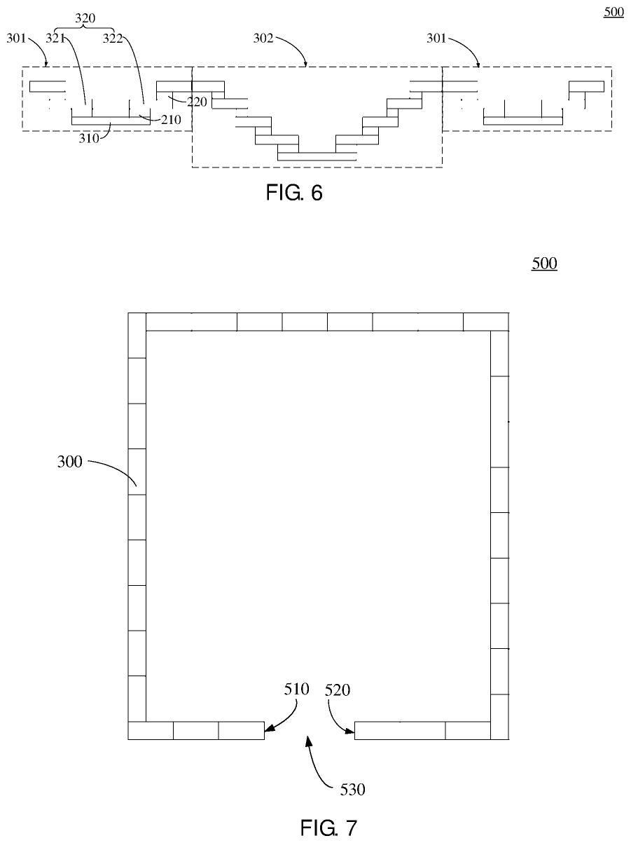

Quantities of metal segment groups 320 in the detection units 300 may be the same. For example, in the embodiment shown in FIG. 5, each detection unit 300 includes three metal segment groups 320. In this way, during layout design, the structure for detecting a crack may be formed in an array form to improve layout design efficiency. In other embodiments, the quantities of metal segment groups 320 in the detection units 300 may alternatively be different. For example, as shown in FIG. 6, each detection unit 300 may include a first detection unit 301 and a second detection unit 302, where the first detection unit 301 includes two metal segment groups 320, and the second detection unit 302 includes four metal segment groups 320. The multiple detection units 300 are arranged in an order of a first detection unit 301, a second detection unit 302, a first detection unit 301, a second detection unit 302, . . . , and so on. In this way, a detection range of the structure for detecting a crack can be increased while reliability of the connection between the metal segments of the structure for detecting a crack can be ensured, thereby further improving detection accuracy of the structure for detecting a crack. Certainly, it can be understood that the multiple detection units 300 may further include three or more detection units 300 having different quantities of metal segment groups 320, and the arrangement manner may be designed according to specific detection requirements. This is not limited in the present disclosure.

In an exemplary embodiment of the present disclosure, as shown in FIG. 7, the multiple detection units 300 are connected end to end to form a detector ring 500 with an opening 530. For example, in two adjacent detection units 300, a second metal segment 322 of one detection unit 300 is connected to a first metal segment 321 of the adjacent detection unit 300. It can be understood that the detector ring 500 described herein refers to a ring shape as a whole, which is actually a wave shape in a longitudinal cross-sectional view. The detector ring 500 formed by the multiple detection units 300 connected end to end has a first endpoint 510 and a second endpoint 520. The first endpoint 510 and the second endpoint 520 are spaced apart from each other, such that an opening 530 is formed between the first endpoint 510 and the second endpoint 520. The first endpoint 510 may be used as an input terminal of the detector ring 500, and the second endpoint 520 may be used as an output terminal of the detector ring 500. The first endpoint 510 and the second endpoint 520 may be located in a same metal layer 100. In this way, connection lines can be simultaneously arranged in the metal layer 100 to connect detection circuits for crack detection. The first endpoint 510 and the second endpoint 520 may alternatively be located in different metal layers 100. In this case, connection lines can be provided between the first endpoint 510 and the second endpoint 520 for connection to the detection circuit.

The structure for detecting a crack further includes a detection circuit. The detector ring 500 is connected to the detection circuit at the opening 530, that is, the detection circuit is connected to the input terminal and the output terminal to implement crack detection. For example, a detection signal is transmitted through the input terminal of the detector ring 500, and then the signal is received through the output terminal of the detector ring 500. When the detector ring 500 is damaged by stress during slicing, the output terminal cannot receive the signal, or a received signal changes and does not correspond to a preset standard output signal. If the detector ring 500 is not damaged, the signal received by the output terminal corresponds to the preset standard output signal. Certainly, it can be understood that the multiple detection units 300 may be connected end to end to form another shape, for example, form multiple long metal lines extending along edges of the chip.

In some embodiments, as shown in FIG. 5, the intermediate metal segments 310 in the detection units 300 in the detector ring 500 are located in a same metal layer 100, such that the intermediate metal segments 310 can be arrayed in one metal layer 100 during layout design to improve layout design efficiency. In some other embodiments, as shown in FIG. 6, the intermediate metal segments 310 in the detection units 300 in the detector ring 500 are located in different metal layers 100, such that different intermediate metal segments 310 are distributed in different positions of the structure for detecting a crack, thereby further improving a detection range of the structure for detecting a crack to improve crack detection accuracy.

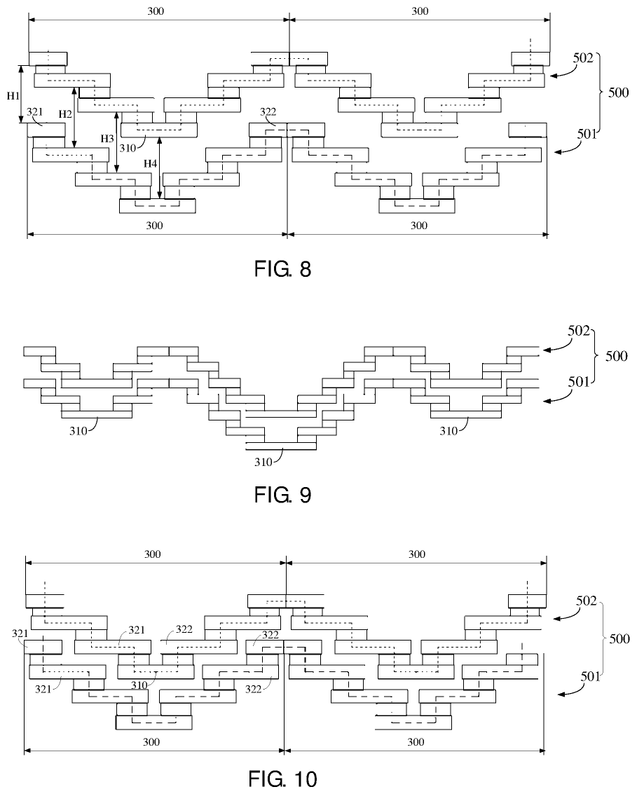

As shown in FIG. 5 and FIG. 6, there may be one detector ring 500 formed by the multiple detection units 300. In other embodiments, there may be multiple detector rings 500 formed by the multiple detection units 300, and the multiple detector rings 500 are spaced apart from one another. For example, as shown in FIG. 8, the multiple detection units 300 form two detector rings 500 spaced apart from each other. Each of the detector rings 500 is connected to the detection circuit at the opening 530. The detection circuit may be provided in correspondence with the detector ring 500, that is, each detector ring 500 is correspondingly connected to a detection circuit, or multiple detector rings 500 may share one detection circuit. For example, detection circuits are connected to multiple detector rings 500 in a one-to-one correspondence through multiple connection lines that can be enabled or disabled.

In some embodiments, as shown in FIG. 8, intermediate metal segments 310 in detection units 300 in a same detector ring 500 are located in a same metal layer 100, such that the intermediate metal segments 310 can be arrayed in one metal layer 100 during layout design to improve layout design efficiency. In some other embodiments, as shown in FIG. 9, intermediate metal segments 310 in detection units 300 in a same detector ring 500 are located in different metal layers 100, such that different intermediate metal segments 310 are distributed in different positions of the structure for detecting a crack, thereby further improving a detection range of the structure for detecting a crack to improve crack detection accuracy.

It can be understood that, that the detector rings 500 are spaced apart means that there is no connection relationship between the detector rings 500, and the detector rings 500 may be completed spaced apart in the longitudinal direction, for example, the direction A. For example, in adjacent detector rings 500, the uppermost metal layer 100 of the detector ring 500 located on the lower side is provided lower than the lowermost metal layer 100 of the detector ring 500 located on the upper side. Alternatively, the detector rings 500 may be partially interlaced in the longitudinal direction. In an exemplary embodiment, as shown in FIG. 8, the detection units 300 in the detector rings 500 are provided in a one-to-one correspondence. An intermediate metal segment 310 of a detection unit 300 in one of adjacent detector rings 500 and a metal segment group 320 in a corresponding detection unit 300 in the other of the adjacent detector rings 500 are located in a same metal layer 100.

That the detection units 300 are correspondingly provided means that positions thereof correspond to each other in an upper and lower direction. For example, as shown in FIG. 8, two detector rings 500 are respectively a first detector ring 501 and a second detector ring 502 located above the first detector ring 501, and positions of a detection unit 300 in the first detector ring 501 and a detection unit 300 in the second detector ring 502 correspond to each other in the upper and lower direction. For example, projection of the detection unit 300 in the first detector ring 501 on a first plane coincides with projection of the detection unit 300 in the second detector ring 502 on the first plane. Further, a position of an intermediate metal segment 310 of a detection unit 300 in one of adjacent detector rings 500 and a position of an intermediate metal segment 310 of a corresponding detection unit 300 in the other of the adjacent detector rings 500 are provided corresponding to each other, that is, positions of the intermediate metal segments 310 in the adjacent detector rings 500 correspond to each other in the upper and lower direction. For example, projection of an intermediate metal segment 310 of a detection unit 300 in the first detector ring 501 on the first plane coincides with projection of an intermediate metal segment 310 of a corresponding detection unit 300 in the second detector ring 502 on the first plane.

In this embodiment, an intermediate metal segment 310 of one detector ring 500 and a metal segment group 320 of the other detector ring 500 are provided in the same layer, such that there are overlapping regions in detection ranges of different detector rings 500, thereby further improving crack detection precision and sensitivity. For example, as shown in FIG. 8, in two detection units 300 whose positions correspond to each other in the upper and lower direction, an intermediate metal segment 310 in the detection unit 300 located on the upper side is located between a first metal segment 321 and a second metal segment 322 in the detection unit 300 located on the lower side.

In one embodiment, at least one metal segment group 320 of a detection unit 300 of one of adjacent detector rings 500 and a metal segment group 320 in a corresponding detection unit 300 of the other of the adjacent detector rings 500 are located in a same metal layer 100, such that overlapping regions of detection ranges of different detector rings 500 are further increased, thereby further improving crack detection precision and sensitivity.

For example, as shown in FIG. 10, an intermediate metal segment 310 of a detection unit 300 in the second detector ring 502 and a metal segment group 320 in a second metal layer (counting from top to bottom) of a corresponding detection unit 300 in the first detector ring 501 are provided in a same layer, and a metal segment group 320 in a third metal layer (counting from top to bottom) of the detection unit 300 in the second detector ring 502 and a metal segment group 320 in a first metal layer (that is, the uppermost layer) in the corresponding detection unit 300 in the first detector ring 501 are provided in a same layer, such that both the detector rings 500 have overlapping regions in both the metal layers 100, thereby improving crack detection precision and sensitivity.

In an exemplary embodiment, a spacing between corresponding intermediate metal segments 310 of adjacent detector rings 500 is equal to a spacing between corresponding metal segment groups 320 in the adjacent detector rings 500, such that spacings between positions of the detector rings 500 are equal, thereby preventing signal interference from being generated due to spacings not equal to each other and preventing detection accuracy from being affected.

For example, as shown in FIG. 8, a spacing between a metal segment group 320 of the detection unit 300 in the first detector ring 501 in the first metal layer and a metal segment group 320 of the detection unit 300 in the second detector ring 502 in the first metal layer is H1, a spacing between a metal segment group 320 of the detection unit 300 in the first detector ring 501 in the second metal layer and a metal segment group 320 of the detection unit 300 in the second detector ring 502 in the second metal layer is H2, a spacing between a metal segment group 320 of the detection unit 300 in the first detector ring 501 in the third metal layer and a metal segment group 320 of the detection unit 300 in the second detector ring 502 in the third metal layer is H3, and a spacing between the intermediate metal segment 310 of the detection unit 300 in the first detector ring 501 and the intermediate metal segment 310 of the detection unit 300 in the second detector ring 502 is H4. In this case, H1=H2=H3=H4.

In other embodiments, intermediate metal segments 310 in one or more detection units 300 may be replaced with active layers. For example, in an embodiment in which multiple detection units 300 constitute a first detector ring 501 and a second detector ring 502, intermediate metal segments 310 of detection units 300 in the first detector ring 501 located on the lower side are replaced with active layers.

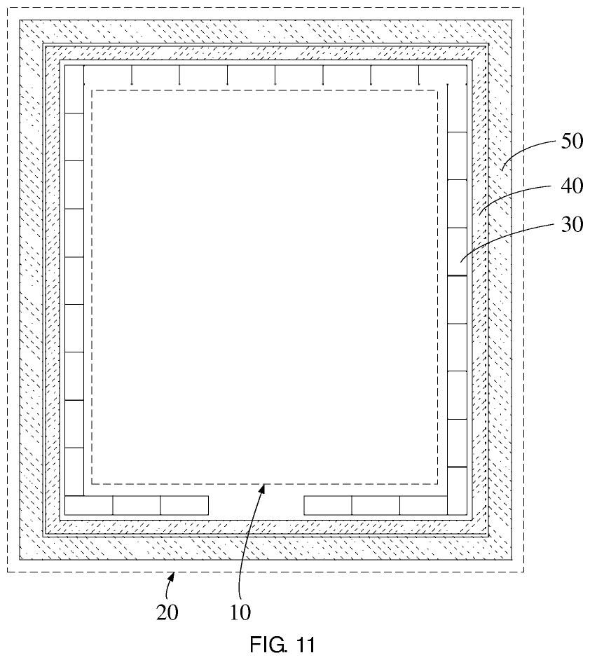

An exemplary embodiment of the present disclosure further provides a semiconductor device. As shown in FIG. 11, the semiconductor device has a chip region 10 and a peripheral region 20 surrounding the chip region 10. The structure for detecting a crack described above is provided in the peripheral region 20.

In the semiconductor device provided in this embodiment, multiple detection units 300 are provided in the structure for detecting a crack, the detection units 300 each include an intermediate metal segment 310 and at least two metal segment groups 320, the intermediate metal segment 310 and each of the metal segment groups 320 are located in different metal layers 100, and along a direction from the intermediate metal segment 310 to the metal segment group 320, a distance between an outer endpoint of a first metal segment 321 and an outer endpoint of a second metal segment 322 in the metal segment group 320 gradually increases to form a step-shaped structure crossing multiple metal layers, such that the detection unit 300 can reflect a crack status of the multiple metal layers 100, and the step-shaped structure can enable the detection unit 300 to extend as long as possible on an edge of a chip at which the detection unit 300 is located while crossing as many metal layers 100 as possible, which can improve detection accuracy of the detection unit 300 and reduce costs.

As described above, the multiple detection units 300 may constitute the detector ring 500, and the detector ring 500 is surrounding the chip region 10, such that crack detection of an entire edge region of the chip region 10 is implemented through the detector ring 500, thereby ensuring circuit stability of the semiconductor chip obtained through preparation.

In an exemplary embodiment of the present disclosure, as shown in FIG. 11, the semiconductor device further includes a protection ring 40 and a slicing slot 50. The protection ring 40 is surrounding the detector ring 500. The slicing slot 50 is surrounding the protection ring 40. The slicing slot 50 is used to indicate a slicing position. The protection ring 40 is provided to reduce extension of cracks into the chip region and to prevent penetration of external moisture into the chip region 10.

The embodiments or implementations of this specification are described in a progressive manner, and each embodiment focuses on differences from other embodiments. The same or similar parts between the embodiments may refer to each other.

In the description of the specification, the description with reference to terms such as “an embodiment”, “an exemplary embodiment”, “some implementations”, “a schematic implementation”, and “an example” means that the specific feature, structure, material, or characteristic described in combination with the implementation(s) or example(s) is included in at least one implementation or example of the present disclosure.

In this specification, the schematic expression of the above terms does not necessarily refer to the same implementation or example. Moreover, the described specific feature, structure, material or characteristic may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned apparatus or element must have a specific orientation and must be constructed and operated in a specific orientation. Therefore, these terms should not be construed as a limitation to the present disclosure.

It can be understood that the terms such as “first” and “second” used in the present disclosure can be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process, and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

In the structure for detecting a crack and the semiconductor device provided in the embodiments of the present disclosure, multiple detection units are provided, the detection units each include an intermediate metal segment and at least two metal segment groups, the intermediate metal segment and each of the metal segment groups are located in different metal layers, and along a direction from the intermediate metal segment to the metal segment group, a distance between an outer endpoint of a first metal segment and an outer endpoint of a second metal segment in the metal segment group gradually increases to form a step-shaped structure crossing multiple metal layers, such that the detection unit can reflect a crack status of the multiple metal layers, and the step-shaped structure can enable the detection unit to extend as long as possible on an edge of a chip at which the detection unit is located while crossing as many metal layers as possible, which can improve detection accuracy of the detection unit and reduce costs.

1. A structure for detecting a crack, wherein the structure for detecting a crack comprises at least three metal layers, and an interconnection via layer is provided between adjacent metal layers;
the structure for detecting a crack further comprises multiple detection units, the detection unit comprises an intermediate metal segment and at least two metal segment groups, each of the metal segment groups comprises a first metal segment and a second metal segment located in a same metal layer and spaced apart, the intermediate metal segment and each of the metal segment groups are located in different metal layers, and different metal segment groups are located in different metal layers; and
the first metal segment and the second metal segment in a metal segment group adjacent to the intermediate metal segment are respectively connected to the intermediate metal segment through two first interconnection via structures located in a same interconnection via layer; and two first metal segments in adjacent metal segment groups and two second metal segments in the adjacent metal segment groups are respectively connected through two second interconnection via structures located in a same interconnection via layer, wherein
along a direction from the intermediate metal segment to the metal segment group, a distance between an outer endpoint of the first metal segment and an outer endpoint of the second metal segment in a metal segment group away from the intermediate metal segment is greater than a distance between an outer endpoint of the first metal segment and an outer endpoint of the second metal segment in a metal segment group close to the intermediate metal segment.

2. The structure for detecting a crack according to claim 1, wherein a spacing between the first metal segment and the second metal segment in the metal segment group away from the intermediate metal segment is greater than a spacing between the first metal segment and the second metal segment in the metal segment group close to the intermediate metal segment.

3. The structure for detecting a crack according to claim 1, wherein the first metal segment and the second metal segment in a same metal segment group are symmetrically provided with respect to a perpendicular bisector of the intermediate metal segment.

4. The structure for detecting a crack according to claim 1, wherein a number of the metal segment groups in the detection unit is 2 to 5.

5. The structure for detecting a crack according to claim 1, wherein an area of a projection of the intermediate metal segment on a first plane, an area of a projection of the first metal segment on the first plane, and an area of a projection of the second metal segment on the first plane are all larger than an area of a projection of the first interconnection via structure on the first plane and are all larger than an area of a projection of the second interconnection via structure on the first plane, and the first plane is parallel to the metal layer.

6. The structure for detecting a crack according to claim 5, wherein the intermediate metal segment, the first metal segment, the second metal segment, the first interconnection via structure, and the second interconnection via structure are all long strips, and
a length of the intermediate metal segment, a length of the first metal segment, and a length of the second metal segment are all greater than a length of the first interconnection via structure and are all greater than a length of the second interconnection via structure; and/or
a width of the intermediate metal segment, a width of the first metal segment, and a width of the second metal segment are all greater than a width of the first interconnection via structure and are all greater than a width of the second interconnection via structure.

7. The structure for detecting a crack according to claim 1, wherein the multiple detection units are connected end to end to form a detector ring with an opening, and the structure for detecting a crack further comprises a detection circuit; and
the detector ring is connected to the detection circuit at the opening.

8. The structure for detecting a crack according to claim 7, wherein the intermediate metal segments in the detection units in the detector ring are located in a same metal layer.

9. The structure for detecting a crack according to claim 7, wherein the multiple detection units constitute at least two detector rings spaced apart from each other.

10. The structure for detecting a crack according to claim 9, wherein the intermediate metal segments in the detection units in a same detector ring are located in a same metal layer.

11. The structure for detecting a crack according to claim 9, wherein the detection units in the detector rings are provided in a one-to-one correspondence, and the intermediate metal segment of the detection unit in one of adjacent detector rings and the metal segment group in a corresponding detection unit in the other of the adjacent detector rings are located in a same metal layer.

12. The structure for detecting a crack according to claim 11, wherein at least one metal segment group of the detection unit in one of the adjacent detector rings and the metal segment group in a corresponding detection unit in the other of the adjacent detector rings are located in a same metal layer.

13. The structure for detecting a crack according to claim 9, wherein the detection units in the detector rings are provided in a one-to-one correspondence, and a position of the intermediate metal segment of the detection unit in one of adjacent detector rings and a position of the intermediate metal segment of a corresponding detection unit in the other of the adjacent detector rings are provided corresponding to each other.

14. The structure for detecting a crack according to claim 9, wherein a spacing between corresponding intermediate metal segments of adjacent detector rings is equal to a spacing between corresponding metal segment groups in the adjacent detector rings.

15. A semiconductor device, comprising a chip region and a peripheral region surrounding the chip region, wherein the structure for detecting a crack according to claim 1 is provided in the peripheral region.

16. The semiconductor device according to claim 15, wherein a detector ring formed by multiple detection units surrounds the chip region.

17. The semiconductor device according to claim 15, further comprising:
a protection ring, surrounding a detector ring; and
a slicing slot, surrounding the protection ring.
